(19) United States
(12) Patent Application Publication
(10) Pub. No.: US 2025/0227877 A1
(43) Pub. Date: Jul. 10, 2025

(54) WATER-COOLING PLATE

(71) Applicant: DELTA ELECTRONICS, INC., Taoyuan City (TW)

(72) Inventors: Kuan-Cheng LU, Taoyuan City (TW); Chih-Hao HSIA, Taoyuan City (TW); Yu-Wei CHEN, Taoyuan City (TW); Wei-Fang WU, Taoyuan City (TW); Meng-Yu CHEN, Taoyuan City (TW)

(21) Appl. No.: 18/913,213

(22) Filed: Oct. 11, 2024

(30) Foreign Application Priority Data
Jan. 9, 2024 (CN) 2024100286572

(51) Int. Cl. H05K 7/20

(52) U.S. Cl. CPC H05K 7/20254; H05K 7/20263; H05K 7/20272

(57) ABSTRACT

This disclosure is directed to a water-cooling plate having a first heat exchanging plate, a second heat exchanging plate and a main body. The first heat exchanging plate has a first fin structure. The second heat exchanging plate has a second fin structure. The main body has a partition plate, a first communication port and a second communication port, the main body has a first recess and a second recess, disposed at two sides of the partition plate. The partition plate has a communication opening communicated to the first recess and the second recess. The first fin structure is accommodated in the first recess to define a first channel, and the second fin structure is accommodated in the second recess to define a second channel. The first communication port, the first channel, the communication opening, the second channel, the second communication port are connected with each other sequentially.

### BACKGROUND OF THE DISCLOSURE

### Technical Field

This disclosure is directed to a water-cooling plate, in particular to a modular water-cooling plate.

### Description of Related Art

A related-art water-cooling plate is used for removing heat generated by a chip in an operation to maintain the chip at an operation temperature. A current approach has two parts of sheet metal or forging disposed up and down and brazed together, so that a closed chamber is defined therein. A fluid is circulated in a flow channel defined in the closed chamber, and the heat generated by the chip is remover by the fluid. Currently, a related-art heat dissipation module disposed corresponding to single circuit board, and the inlet and outlet flow channels of the module are disposed together on a plane, this leads to uneven heat exchange efficiencies at an upstream and a downstream of the fluid. Furthermore, a conventional heat dissipation module occupies a large space, and multiple heat dissipation modules cannot be effectively connected with each other and replaced.

In views of this, in order to solve the above disadvantage, the inventor studied related technology and provided a reasonable and effective solution in this disclosure.

### SUMMARY OF THE DISCLOSURE

This disclosure is directed to a modular water-cooling plate.

This disclosure is directed to a water-cooling plate having a first heat exchanging plate, a second heat exchanging plate and a main body. The first heat exchanging plate has a first fin structure protruding from a side thereof. The second heat exchanging plate has a second fin structure protruding from a side thereof. The main body has a partition plate, a first communication port and a second communication port, a first recess and a second recess are defined in the main body, the first recess and the second recess are located opposite to each other at two sides of the partition plate respectively. A communication opening is on the partition plate, the communication opening is communicated with the first recess and the second recess. The first communication port is communicated with the first recess, and the second communication port is communicated with the second recess. A first channel is defined by a first fin structure is accommodated in the first recess, and a second channel is defined by the second fin structure accommodated in the second recess. The first communication port, the first channel, the communication opening, the second channel and the second communication port are connected sequentially in a series.

In one embodiment of this disclosure, the first heat exchanging plate has a first heat exchanging surface, the second heat exchanging plate has a second heat exchanging surface, and an area of the first heat exchanging surface is smaller than an area of the second heat exchanging surface.

In one embodiment of this disclosure, the main body has a third communication port and a fourth communication port, the third communication port is communicated with the first recess, and the fourth communication port is communicated with the second recess. the first heat exchanging plate has a third fin structure protruding therefrom, the second heat exchanging plate has a fourth fin structure protruding therefrom, a third channel is defined by the third fin structure accommodated in the first recess, and a fourth channel is defined by the fourth fin structure accommodated in the second recess. the first channel is non-communicating with the third channel, and the second channel is non-communicating with the fourth channel. A second communication opening communicated with the third channel and the fourth channel is on the partition plate. The third channel is communicated with the third communication port and the fourth channel is communicated with the fourth communication port. The third communication port, the third channel, the second communication opening, the fourth channel and the fourth communication port are connected sequentially in a series.

In one embodiment of this disclosure, the main body has a pair of slopes, the pair of slopes are disposed outside of the main body, the pair of slopes are disposed opposite to each other at two sides of the partition plate respectively, the pair of slopes are respectively tilted relative to the partition plate, an internal angle is defined between each of the slopes and the partition plate, the internal angles are a same to each other, and the pair of slops are non-parallel to each other.

This disclosure is directed to another water-cooling plate having a main body, a first heat exchanging plate and a second heat exchanging plate. The main body has a partition plate, a first communication port and a second communication port, a first recess and a second recess are defined in the main body, the first recess and the second recess located opposite to each other at two sides of the partition plate. The first heat exchanging plate is combined with the first recess to define a first chamber, a first channel is defined in the first chamber, and the first channel is extending on at least a portion of the first heat exchanging plate in the non-straight path manner. A second heat exchanging plate is combined with the second recess to define a second chamber, a second channel is defined in the second chamber, and the second channel is extending on at least a portion of a surface of the second heat exchanging plate in the non-straight path manner. A communication opening is on the partition plate, the communication opening is communicated with the first recess and the second recess. The first communication port is communicated with the first recess, and the second communication port is communicated with the second recess. The first communication port, the first channel, the communication opening, the second channel and the second communication port are connected sequentially in a series.

In one embodiment of this disclosure, the first heat exchanging plate has a first heat exchanging surface, the second heat exchanging plate has a second heat exchanging surface, and an area of the first heat exchanging surface is smaller than an area of the second heat exchanging surface.

In one embodiment of this disclosure, the first heat exchanging plate is combined with the first recess to define a third chamber, a third channel is defined in the third chamber, and the third channel is extending on at least a portion of a surface of the first heat exchanging plate in the non-straight path manner. The second heat exchanging plate is combined with the second recess to define a fourth chamber, a fourth channel is defined in the fourth chamber, and the fourth channel extending on at least a portion of a surface of the second heat exchanging plate in the non-straight path manner, and the fourth channel is extending on at least a portion of a surface of the second heat exchanging plate in the non-straight path manner. The first channel is non-communicating with the third channel, and the second channel is non-communicating with the fourth channel. A second communication opening communicated with the third channel and the fourth channel is on the partition plate. The main body has a third communication port and a fourth communication port, the third communication port is communicated with the first recess, the fourth communication port is communicated with the second recess, the third channel is communicated with the third communication port, and the fourth channel is communicated with the fourth communication port. The third communication port, the third channel, the second communication opening, the fourth channel and the fourth communication port are connected sequentially in a series.

In one embodiment of this disclosure, the main body has a pair of slopes, the pair of slopes are disposed outside of the main body, the pair of slopes are disposed opposite to each other at two sides of the partition plate, the pair of slopes are respectively tilted relative to the partition plate, an internal angle is defined between each of the slopes and the partition plate, the internal angles are a same to each other, and the pair of slops are non-parallel to each other.

This disclosure provides a modular water-cooling plate with stacked chambers corresponding to each heat exchanging surface so as to prevent a heat exchange efficiency of the working fluid at downstream from over decreasing. The water-cooling plate have heat exchanging surfaces at two sides thereof with different area so as to optimize a ratio of the heat exchange efficiencies at two sides of the water-cooling plate. Flow channels are defined in the chambers respectively and each channel is extended to cover a side of opposite to the heat exchanging surfaces so as to extend a period of heat exchanging. The water-cooling plates may be coupled with each other to extend via the slopes on its edges or disposed in a stack and therefore suitable for various shapes of heat sources. A heat dissipation efficiency of unit volume is a space where the water-cooling plate is disposed is efficiently improved. The module requires smaller space, and flow loops can be connected in series or parallel according to operation environments. Additionally, the module can be replaced readily. As a result, the water-cooling module is compact, a pressure drop in the module in operation is effectively reduced, the heat dissipation areas are enlarged, space occupation is more efficient.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing a water-cooling plate according to an embodiment of this disclosure.

FIGS. 2 and 3 are exploded views showing the water-cooling plate according to aforementioned embodiment of this disclosure.

FIG. 4 is a cross-sectional view of a first recess and a second recess of the water-cooling plate according to aforementioned embodiment of this disclosure.

FIG. 5 is another cross-sectional view of the first recess and the second recess of the water-cooling plate according to aforementioned embodiment of this disclosure.

FIG. 6 is a cross-sectional view of the first recess of the water-cooling plate according to aforementioned embodiment of this disclosure.

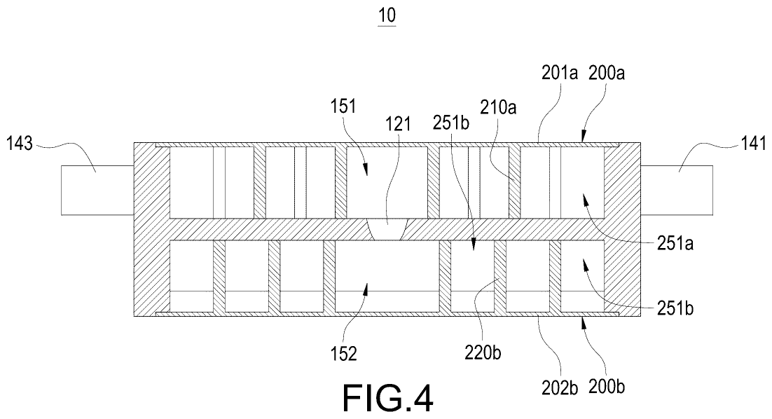

FIG. 4 is a cross-sectional view of the second recess of the water-cooling plate according to aforementioned embodiment of this disclosure.

FIG. 8 is a perspective view showing another operation status of the water-cooling plate according to an embodiment of this disclosure.

FIG. 9 is a perspective view showing another operation status of the water-cooling plate according to an embodiment of this disclosure.

FIGS. 10 and 11 are perspective views showing further another operation status of the water-cooling plate according to an embodiment of this disclosure.

FIGS. 12 and 13 are exploded views showing the water-cooling plate according to another embodiment of this disclosure.

FIG. 14 is a cross-sectional view of the first recess of the water-cooling plate according to aforementioned another embodiment of this disclosure.

FIG. 15 is a cross-sectional view of the second recess of the water-cooling plate according to aforementioned another embodiment of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

Detailed descriptions and technical contents of this disclosure is described in the flowing paragraph with reference to the drawings. However, the drawings are attached only for illustration and are not intended to limit this disclosure.

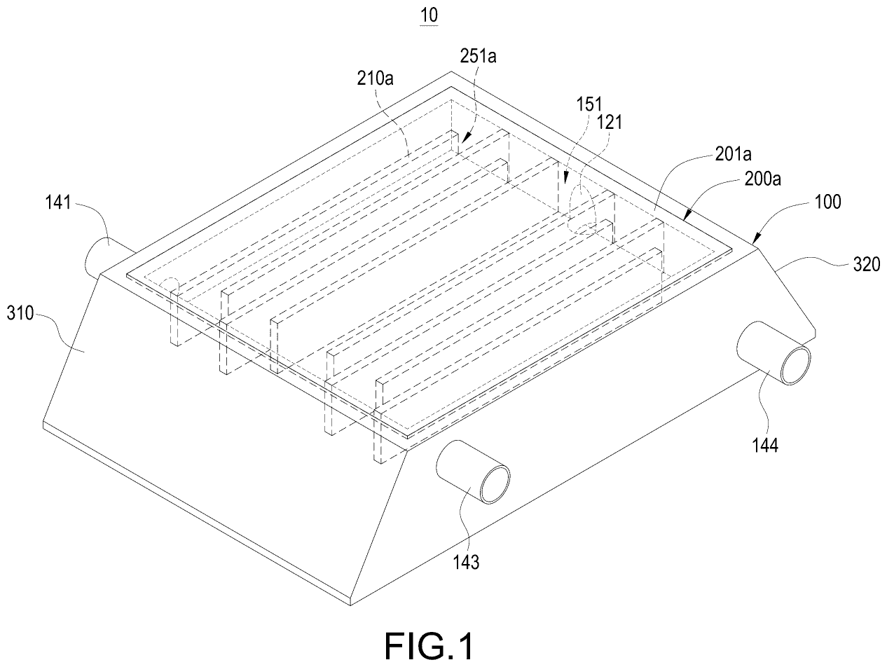

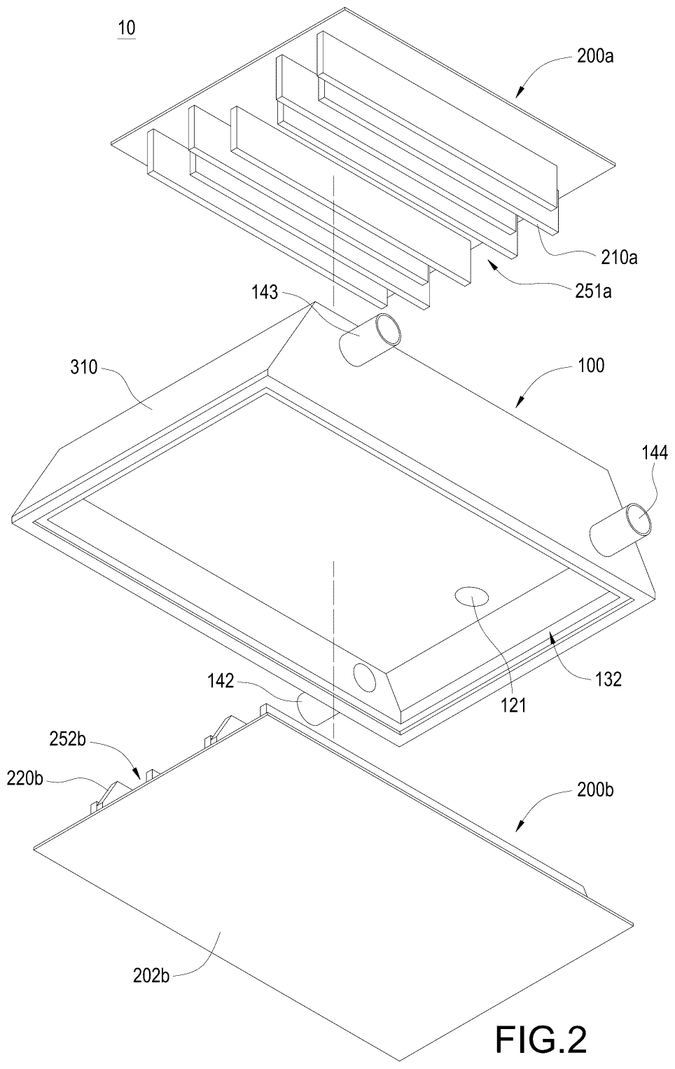

According to FIGS. 1 to 3, an embodiment of this disclosure provides a water-cooling plate 10 which is used for contacting at least a heat source (not shown in FIGS.) and allows a working fluid (not shown in FIGS.) to pass therein. This water-cooling plate 10 is used as an interface for heat exchanging between the heat source and the working fluid. The water-cooling plate 10 has a main body 100, a first heat exchanging plate 200a and a second heat exchanging plate 200b.

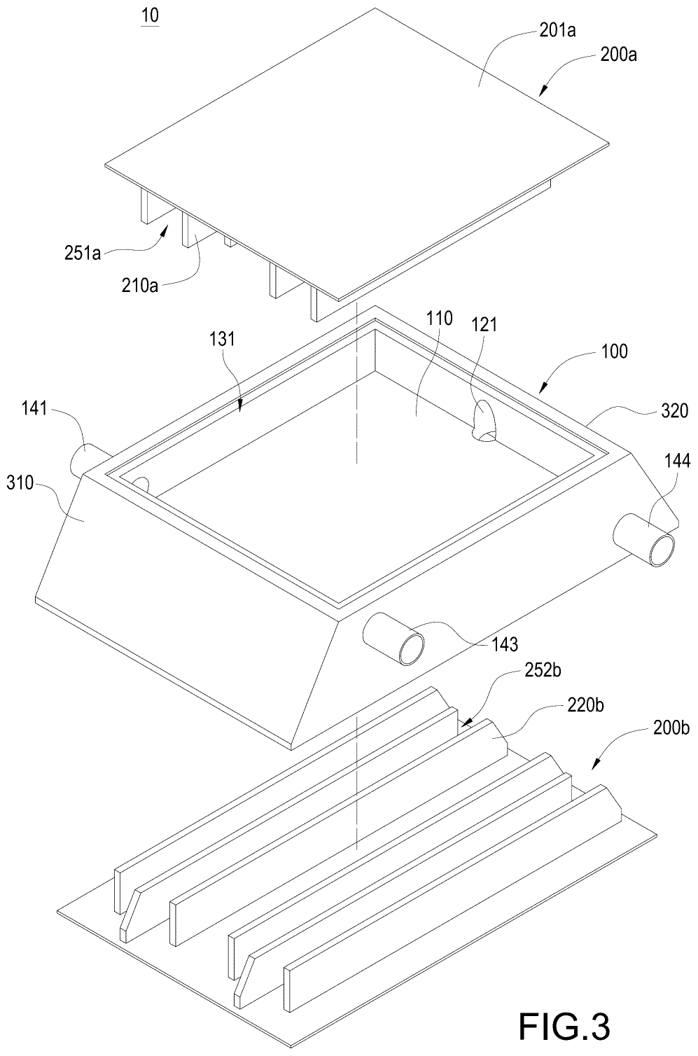

According to this embodiment as shown in FIGS. 2 to 3, the main body 100 is a flat housing with two opened side, but scopes of this disclosure should not be limited to the embodiment. A partition plate 110 is arranged in the main body 100, the main body 100 has a first communication port 141 and a second communication port 142 disposed at an outside thereof, and the first communication port 141 and the second communication port 142 are respectively communicated with an internal of the main body 100. Specifically, a first recess 131 and a second recess 132 are defined in the main body 100, and the first recess 131 and the second recess 132 are located opposite to each other at two sides of the partition plate 110. A communication opening 121 is on the partition plate 110, the communication opening 121 is communicated with the first recess 131 and the second recess 132. The first communication port 141 is communicated with the first recess 131, and the second communication port 142 is communicated with the second recess 132.

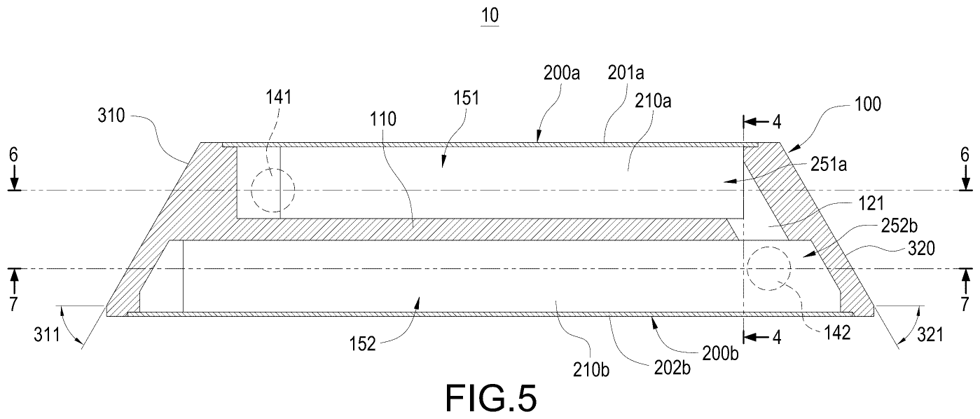

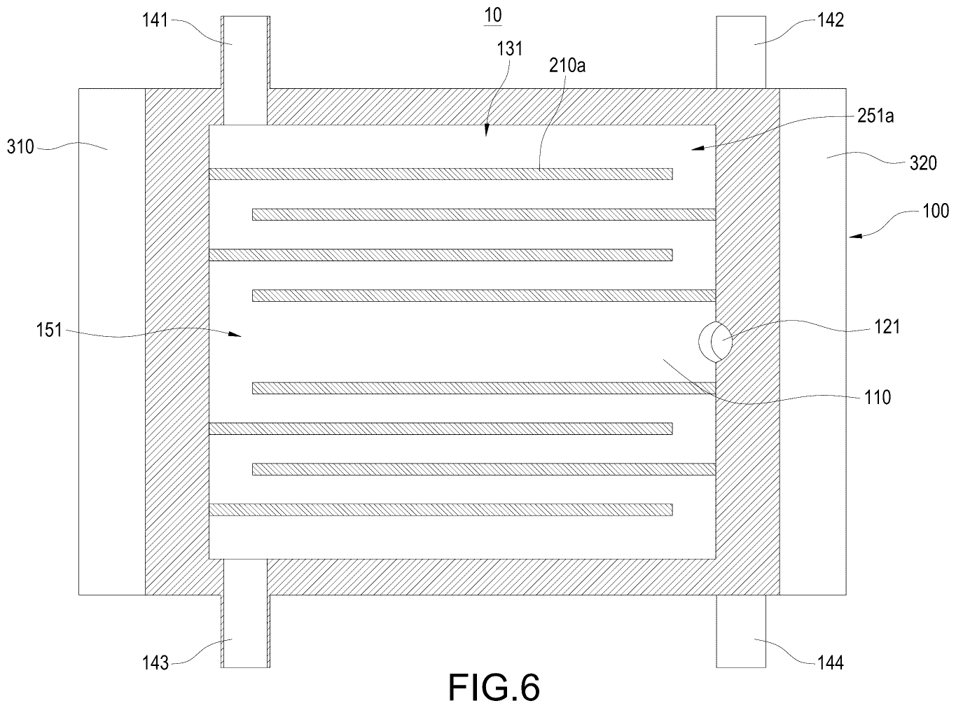

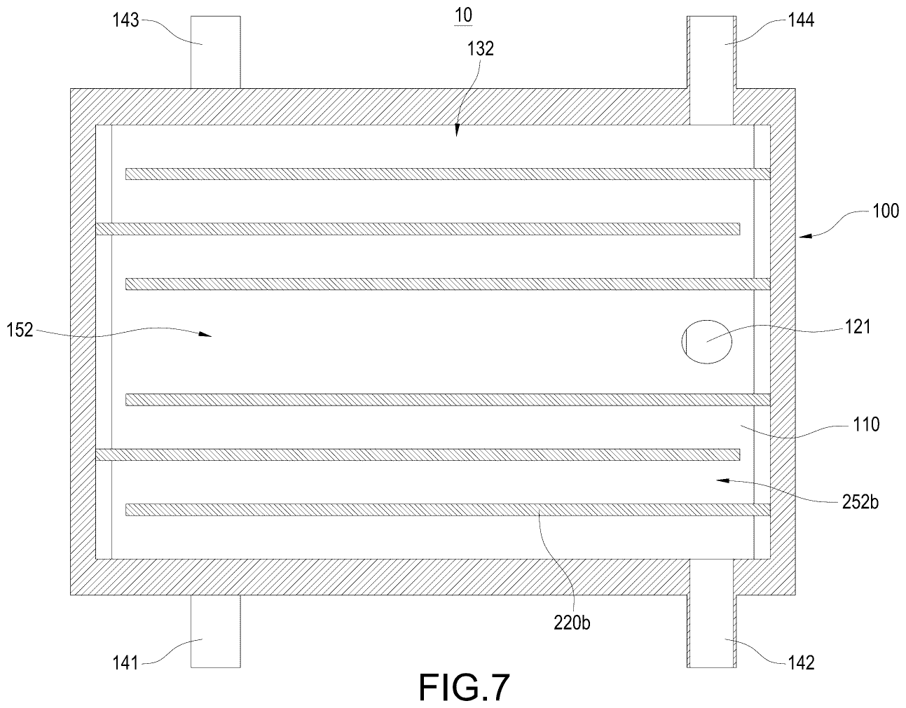

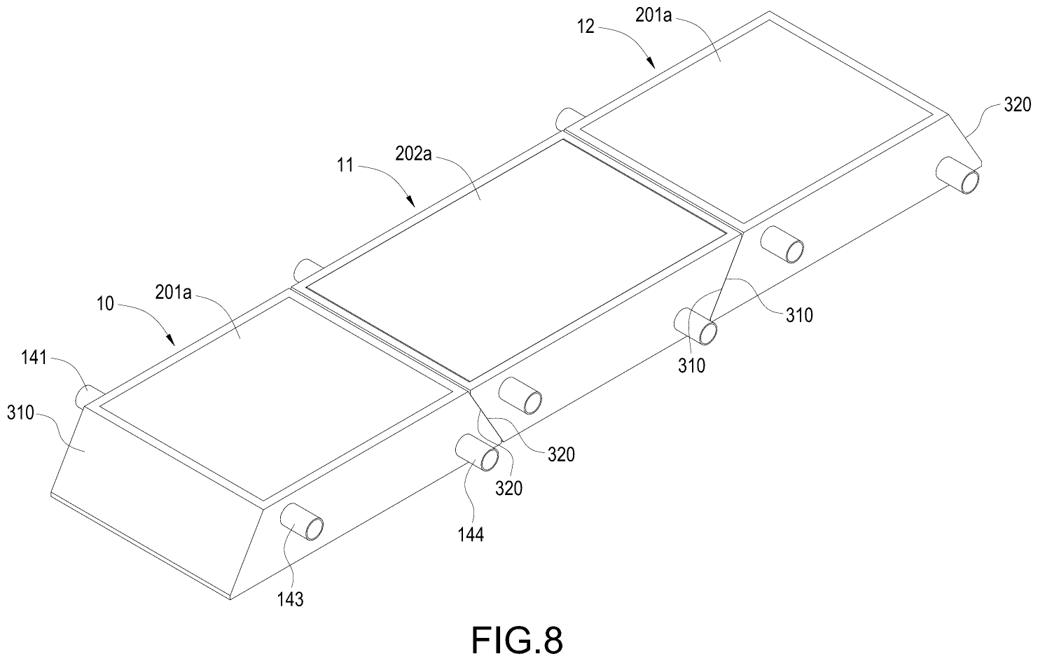

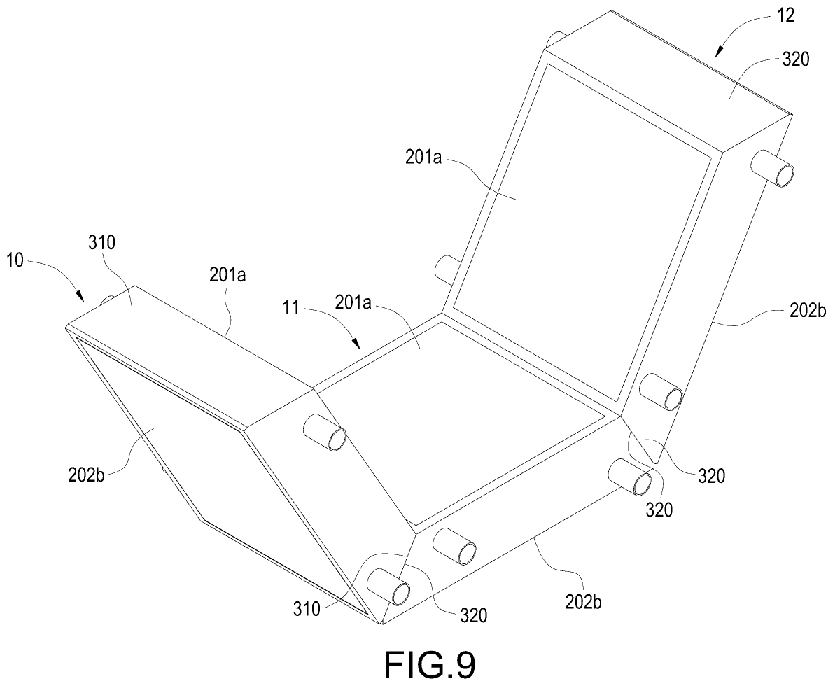

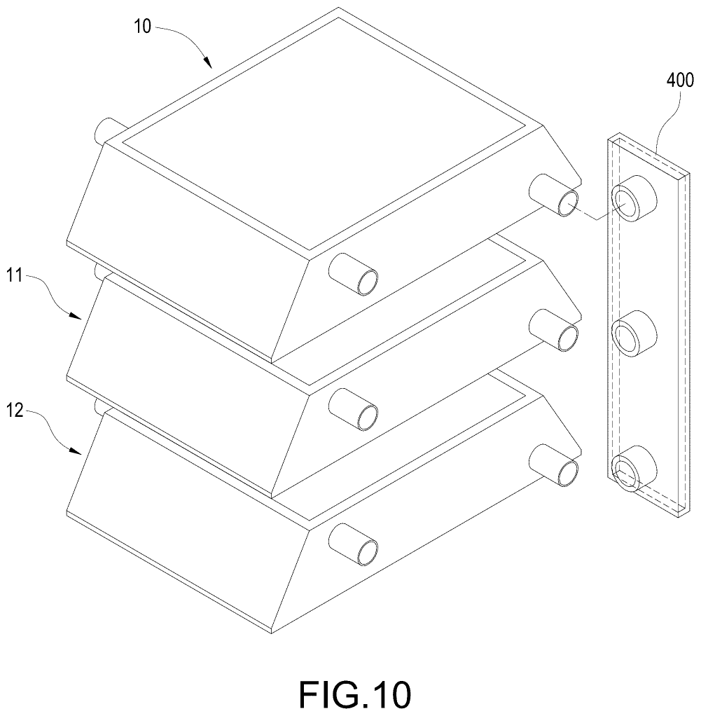

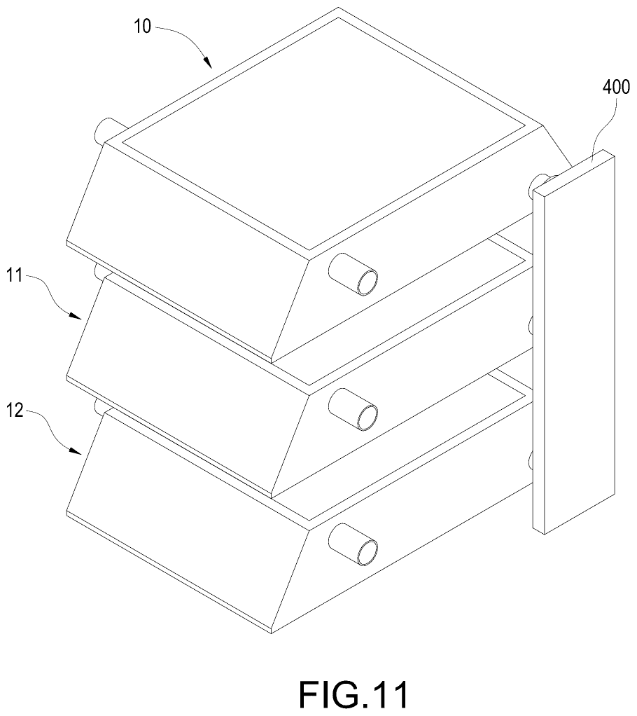

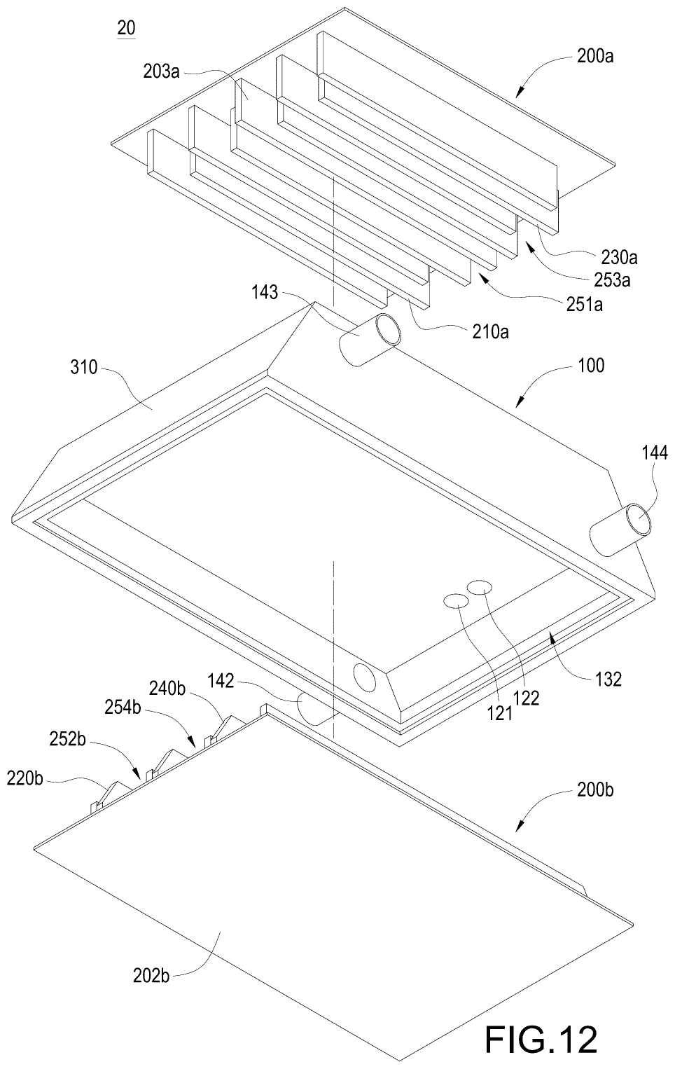

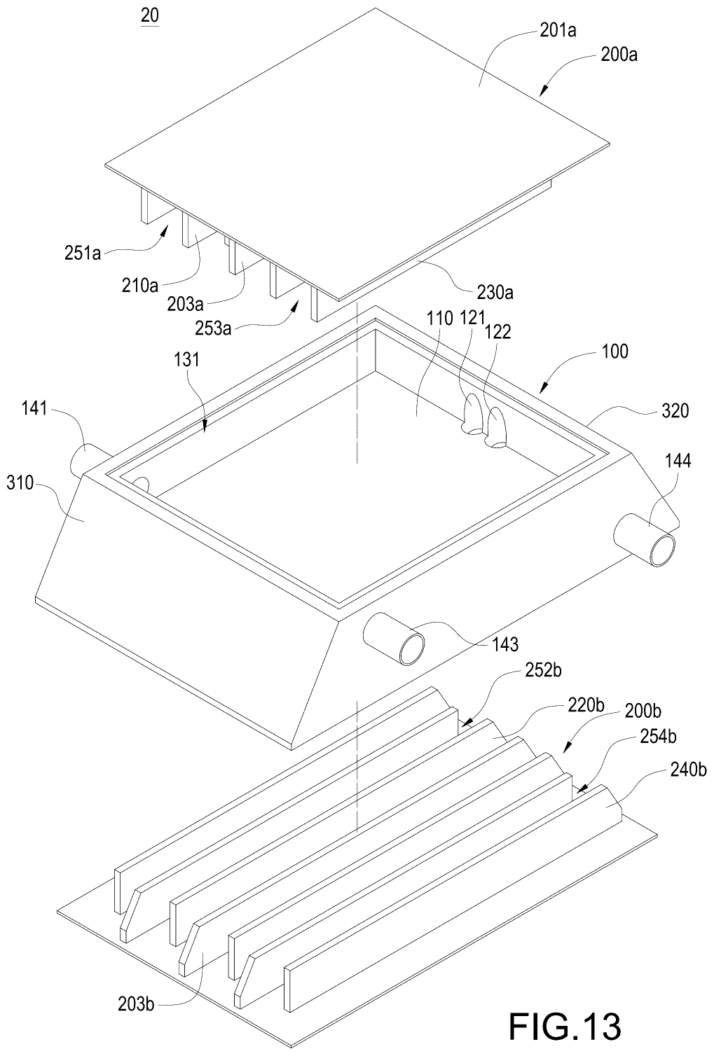

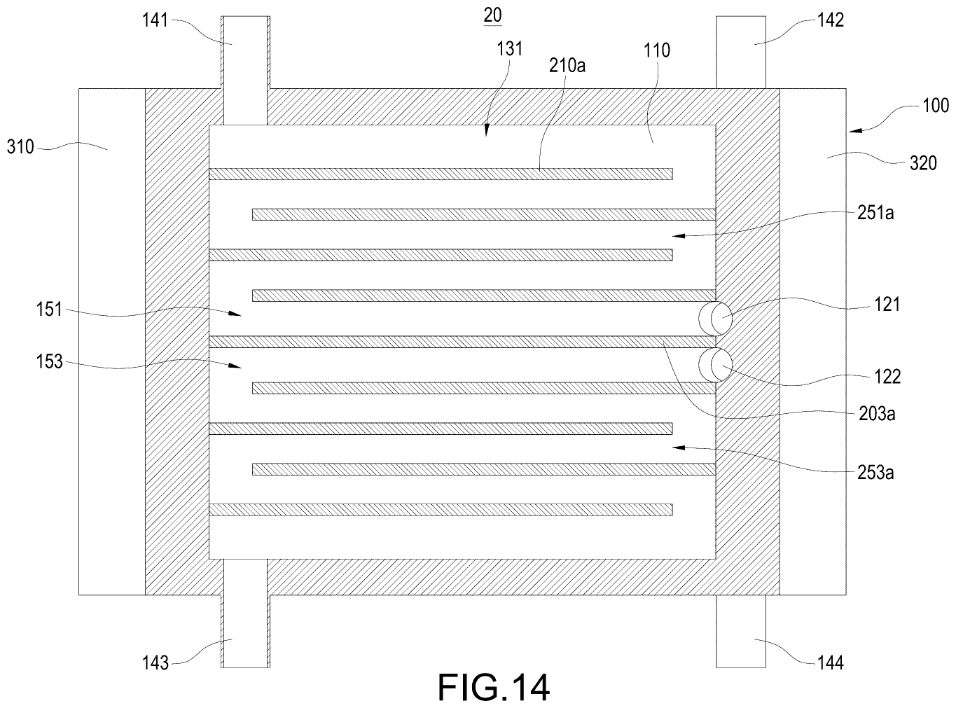

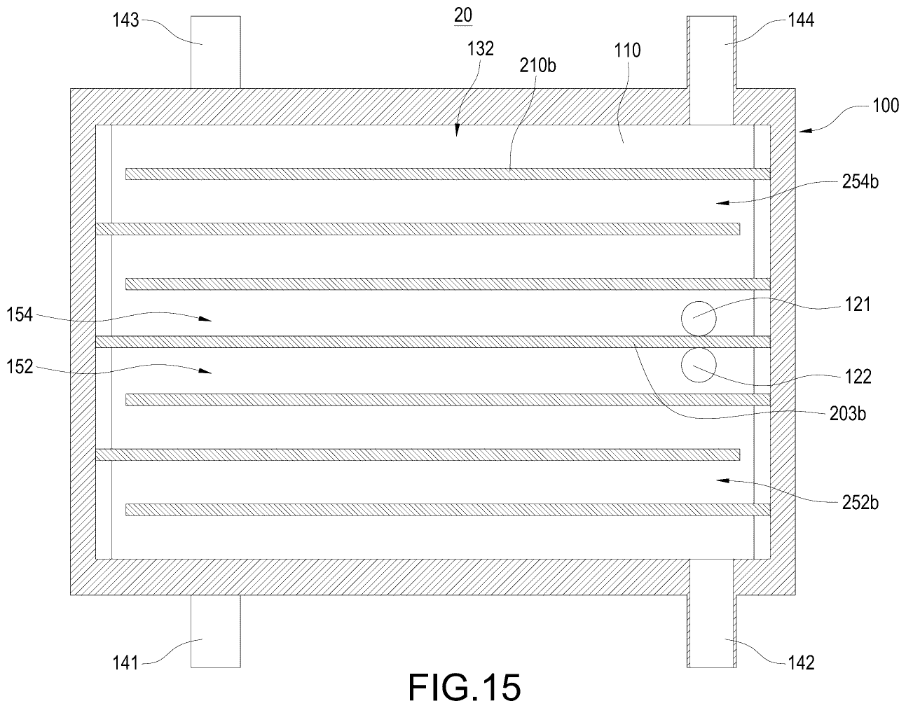

According to FIGS. 1 to 5, first heat exchanging plate 200a has a first heat exchanging surface 201a and a first fin structure 210a, the first fin structure 210a is disposed protrusively on a surface of the first heat exchanging plate 200a opposite to the first heat exchanging surface 201a. The first heat exchanging surface 201a is configured for contacting the heat source for absorbing heat into the first heat exchanging plate 200a from the heat source. The first heat exchanging plate 200a is combined with the first recess 131 to define a first chamber 151, and a first channel 251a is defined in first chamber 151 by the first fin structure 210a accommodated in the first recess 131. According to FIGS. 1 and 4 to 6, the first channel 251a is extending on at least a portion of a surface of the first heat exchanging plate 200a in the non-straight path manner. According to this embodiment, the first channel 251a is extended to cover a surface at a side of the first heat exchanging plate 200a opposite to the first heat exchanging surface 201a, but scopes of this disclosure should not be limited to the embodiment. In this embodiment, the non-straight path is a tortuous path, but scopes of this disclosure should not be limited to the embodiment. For example, the non-straight path may be a vortex path.

According to FIGS. 3 to 5, the second heat exchanging plate 200b has a second heat exchanging surface 202b and a second fin structure 220b, the second fin structure 220b is disposed protrusively on a surface of the second heat exchanging plate 200b opposite to the second heat exchanging surface 202b. The second heat exchanging surface 202b is configured for contacting the heat source for absorbing heat into the second heat exchanging plate 200b from the heat source. The second heat exchanging plate 200b is combined with the second recess 132 to define a second chamber 152, and a second channel 252b is defined in the second chamber 152 by the second fin structure 220b accommodated in the first recess 131.

According to FIGS. 4 and 5 to 7, the second channel 252b is extending on at least a portion of a surface of the second heat exchanging plate 200b in the non-straight path manner. In this embodiment, the second channel 252b is extending to cover a surface on a side of the second heat exchanging plate 200b opposite to the second heat exchanging surface 202b, but scopes of this disclosure should not be limited to the embodiment. In this embodiment, the non-straight path is a tortuous path, but scopes of this disclosure should not be limited to the embodiment. For example, the non-straight path may be a vortex path.

According to FIGS. 4 to 7, the first communication port 141, the first channel 251a, the communication opening 121, the second channel 252b and the second communication port 142 mentioned above are connected sequentially in a series to define a heat dissipation loop. The working fluid may be input into the first channel 251a through the first communication port 141, the working fluid is thermally exchanged with the first heat exchanging plate 200a when passing the first channel 251a, than the working fluid is input into the second channel 252b to be thermally exchanged with the second heat exchanging plate 200b, and the working fluid is finally output from the water-cooling plate 10 through the second communication port 142 to transfer heat out of the water-cooling plate 10. The working fluid may be reversed to flow through the water-cooling plate 10 for heat exchanging.

According to and embodiment as shown in FIGS. 1 to 3, the first fin structure 210a is disposed protrusively on the first heat exchanging plate 200a, the second fin structure 220b is disposed protrusively on the second heat exchanging plate 200b. Accordingly, only a partition plate 110 is arranged in the main body 100 to define the first recess 131 and the second recess 132. The first channel 251a and the second channel 252b can be defined by assembling the first heat exchanging plate 200a and the second heat exchanging plate 200b to the first recess 131 and the second recess 132 respectively. Accordingly, the water-cooling plate 10 of this disclosure has parts with simple structure and easy to be manufactured, and it is convenient to be assembled. An upstream and a downstream of the flow channels in the main body 100 are arranged in stacked layers to avoid an over decreasing of heat exchange efficiency between the upstream and the downstream. Moreover, the first channel 251a is extending on at least a portion of the surface of the first heat exchanging plate 200a in the non-straight path manner, and the second channel 252b is extending on at least a portion of the surface of the second heat exchanging plate 200b in the non-straight path manner, thereby improving the heat exchange efficiency of the water-cooling plate 10.

According to this embodiment, an area of the first heat exchanging surface 201a is smaller than an area of the second heat exchanging surface 202b so as to perform an optimized ratio of the heat exchange efficiencies at two sides of the water-cooling plate 10. For example, in an operation, the working fluid is transferred firstly through the first heat exchanging plate 200a than through the second heat exchanging plate 200b, so that the working fluid exchange heat with the first heat exchanging plate 200a with a period long than a period that exchange heat with the second heat exchanging plate 200b.

According to FIGS. 4 to 7, in a minimum condition capable of achieving predetermined functions of this disclosure, the main body 100 has a first communication port 141 and a second communication port 142. However, in this embodiment, the main body 100 may further has a third communication port 143 and a fourth communication port 144 disposed at outside thereof, and the third communication port 143 and the fourth communication port 144 are communicated with an internal of the main body 100 respectively. Specifically, the third communication port 143 is communicated to the first recess 131 so as to communicated with the first channel 251a in the first chamber 151, and the fourth communication port 144 is communicated to the second recess 132 so as to communicated with the second channel 252b in the second chamber 152. Accordingly, the working fluid may pass the water-cooling plate 10 through various directions. This design can further improve the heat exchange efficiency of the water-cooling plate.

According to FIGS. 1 to 5, main body 100 has a pair of slopes 310/320, and the slopes 310/320 are disposed outside of the main body 100, the pair of slopes 310/320 are disposed opposite tot each other at two sides of the partition plate 110, the pair of slopes 310/320 are tilted relative to the partition plate 110 respectively, and an internal angle 311/321 is defined between each slope 310/320 and the partition plate 110, and the internal angles 311/321 are a same to each other and the pair of slopes 310/320 are disposed non-parallel to each other so as to dissipate heat in various dimensions.

According to FIG. 8, a plurality of water-cooling plates 10/11/12 with structures a same to each other may be coupled with each other via the slopes 310/320 so as to extend the first heat exchanging surfaces 201a and/or the second heat exchanging surfaces 202b connected with each other. The first heat exchanging surface 201a and/or the second heat exchanging surface 202b connected with each other may be disposed together in the same plane, so that the water-cooling plates 10 are suitable for a larger heat source. Furthermore, this design is capable of dissipating heat in various dimensions.

According to FIG. 9, a plurality of water-cooling plates 10 with structures a same to each other may be coupled with each other via the slopes 310/320 so as to extend the first heat exchanging surfaces 201a and/or the second heat exchanging surfaces 202b, and an angle may be disposed between the first heat exchanging surface 201a and/or the second heat exchanging surfaces 202b connected with each other, so that the water-cooling plates 10 are suitable for a heat source with an angle and capable of dissipating heat in various dimensions.

According to FIGS. 10 and 11, a plurality of water-cooling plates 10 with structures a same to each other may be separated from each other and disposed parallel to each other, and communicated with each other by a manifold 400, so that the water-cooling plates 10 are suitable for heat sources in a stack and capable of dissipating heat in various dimensions.

According to FIGS. 12 to 15, another embodiment of this disclosure provides a water-cooling plate 20 which is used for contacting at least a heat source (not shown in FIGS.) and allows a working fluid (not shown in FIGS.) to pass therein. This water-cooling plate 20 is used for an interface for heat exchanging between the heat source and the working fluid. The water-cooling plate 20 has a main body 100, a first heat exchanging plate 200a and a second heat exchanging plate 200b.

According to this embodiment, the main body 100 is a flat housing with two opened side, but scopes of this disclosure should not be limited to the embodiment. A partition plate 110 is arranged in the main body 100, the main body 100 has a first communication port 141, a second communication port 142, a third communication port 143 and a disposed at an outside thereof, and the first communication port 141, the second communication port 142, the third communication port 143 and fourth communication port 144 are respectively communicated with an internal of the main body 100. Specifically, a first recess 131 and a second recess 132 are defined in the main body 100, and the first recess 131 and the second recess 132 are located opposite to each other at two sides of the partition plate 110. A communication opening 121 and a second communication opening 122 are defined on the partition plate 110, the communication opening 121 and the second communication opening 122 are communicated with the first recess 131 and the second recess 132. The first communication port 141 and the third communication port 143 are communicated with the first recess 131 respectively, and the second communication port 142 and the fourth communication port 144 are communicated with the second recess 132 respectively.

The first heat exchanging plate 200a has a first heat exchanging surface 201a, a first fin structure 210a and a third fin structure 230a, the first fin structure 210a and the third fin structure 230a are disposed protrusively on the surface of the first heat exchanging plate 200a opposite to the first heat exchanging surface 201a. The first heat exchanging plate 200a has a first wall 203a protruded therefrom, the first fin structure 210a and the third fin structure 230a are disposed at two sides of the first wall 203a respectively. The first heat exchanging surface 201a is configured for contacting the heat source for absorbing heat into the first heat exchanging plate 200a from the heat source. The first heat exchanging plate 200a is combined with the first recess 131, the first recess 131 is separated into a first chamber 151 and a third chamber 153 by the first wall 203a, a first channel 251a is defined in the first chamber 151 by the first fin structure 210a accommodated in the first recess 131, a third channel 253a is defined in the third chamber 153 by the third fin structure 230a accommodated in the first recess 131, and the first channel 251a and the third channel 253a are separated from each other by the first wall 203a so as to be disconnected with each other.

first channel 251a is extending on at least a portion of a surface of first heat exchanging plate 200a in the non-straight path manner, and the third channel 253a is extending on at least a portion of a surface of the first heat exchanging plate 200a in the non-straight path manner. According to this embodiment, the first channel 251a is extended to cover a portion of a surface on the first heat exchanging plate 200a which is opposite to the first heat exchanging surface 201a, and the third channel 253a is extended to cover another portion of the surface on the first heat exchanging plate 200a which is opposite to the first heat exchanging surface 201a, but scopes of this disclosure should not be limited to the embodiment. In this embodiment, the non-straight path is a tortuous path, but scopes of this disclosure should not be limited to the embodiment. For example, the non-straight path may be a vortex path.

The second heat exchanging plate 200b has a second heat exchanging surface 202b, a second fin structure 220b and a fourth fin structure 240b, the second fin structure 220b and the fourth fin structure 240b are disposed protrusively on a surface on the second heat exchanging plate 200b which id opposite to the second heat exchanging surface 202b. A second wall 203b is disposed protrusively on the second heat exchanging plate 200b, the second fin structure 220b and the fourth fin structure 240b are disposed at two sides of the second wall 203b. The second heat exchanging surface 202b is configured for contacting the heat source for absorbing heat into the second heat exchanging plate 200b from the heat source. The second heat exchanging plate 200b is combined with the second recess 132. The second recess 132 is separated in to a second chamber 152 and a fourth chamber 154 by the second wall 203b. A second channel 252b is defined in the second chamber 152 by the second fin structure 220b accommodated in the second recess 132 and a fourth channel 254b is defined in the fourth chamber 154 by the fourth fin structure 240b accommodated in the second recess 132. The second channel 252b and the fourth channel 254b are separated from each other by second wall 203b so as to disconnected with each other. This design can further improve the heat exchange efficiency of the water-cooling plate.

The second channel 252b is extending on at least a portion of a surface of second heat exchanging plate 200b in the non-straight path manner, and the fourth channel 254b is extending on at least a portion of a surface of second heat exchanging plate 200b in the non-straight path manner. According to this embodiment, the second channel 252b is extended to cover a portion of a surface on the second heat exchanging plate 200b which is opposite to the second heat exchanging surface 202b, and the fourth channel 254b is extended to cover another portion of a surface on the second heat exchanging plate 200b which is opposite to the second heat exchanging surface 202b, but scopes of this disclosure should not be limited to the embodiment. In this embodiment, the non-straight path is a tortuous path, but scopes of this disclosure should not be limited to the embodiment. For example, the non-straight path may be a vortex path.

The first communication port 141, the first channel 251a, the communication opening 121, the second channel 252b and the second communication port 142 mentioned above are connected sequentially in a series, and the third communication port 143, the third channel 253a, the second communication opening 122, the fourth channel 254b and the fourth communication port 144 are connected sequentially in a series, so as to define two heat dissipation loops separated from each other. The working fluid may be input into the first channel 251a through the first communication port 141, the working fluid is thermally exchanged with the first heat exchanging plate 200a when passing the first channel 251a, than the working fluid is input into the second channel 252b to be thermally exchanged with the second heat exchanging plate 200b, and the working fluid is finally output from the water-cooling plate 10 through the second communication port 142 to transfer heat out of the water-cooling plate 20. The working fluid may be reversed to flow through the water-cooling plate 20 for heat exchanging. This design can further improve the heat exchange efficiency of the water-cooling plate.

Also, the working fluid may be input into the third channel 253a through the third communication port 143, the working fluid is thermally exchanged with the first heat exchanging plate 200a when passing the first channel 251a, than the working fluid is input into the s fourth channel 254b to be thermally exchanged with the second heat exchanging plate 200b, and the working fluid is finally output from the water-cooling plate 20 through the fourth communication port 144 to transfer heat out of the water-cooling plate 20. The working fluid may be reversed to flow through the water-cooling plate 20 for heat exchanging.

According to this embodiment, the first fin structure 210a is disposed protrusively on the first heat exchanging plate 200a, the second fin structure 220b is disposed protrusively on the second heat exchanging plate 200b. Accordingly, only a partition plate 110 is arranged in the main body 100 to define the first recess 131 and the second recess 132. The first channel 251a, the second channel 252b, the third channel 253a and the fourth channel 254b can be defined by assembling the first heat exchanging plate 200a and the second heat exchanging plate 200b to the first recess 131 and the second recess 132 respectively. Accordingly, the water-cooling plate 20 of this disclosure has parts with simple structure and easy to be manufactured, and it is convenient to be assembled. Moreover, the first channel 251a and the third channel 253a are extending on at least a portion of a surface of the first heat exchanging plate 200a in the non-straight path manner, second channel 252b and the fourth channel 254b are extending on at least a portion of a surface of the second heat exchanging plate 200b in the non-straight path manner, thereby improving a heat exchange efficiency of the water-cooling plate 20. Also, the working fluid can be input into and output from the water-cooling plate 20 through various paths, and the heat exchange efficiency of the water-cooling plate 20 can be further improved.

According to this embodiment, an area of the first heat exchanging surface 201a is smaller than an area of the second heat exchanging surface 202b so as to perform an optimized ratio of the heat exchange efficiencies at two sides of the water-cooling plate 20. For example, in an operation, the working fluid is transferred firstly through the first heat exchanging plate 200a than through second heat exchanging plate 200b, so that the working fluid exchange heat with the first heat exchanging plate 200a with a period long than a period that exchange heat with the second heat exchanging plate 200b.

While this disclosure has been described by means of specific embodiments, numerous modifications and variations could be made thereto by those skilled in the art without departing from the scope and spirit of this disclosure set forth in the claims.

What is claimed is:

1. A water-cooling plate, comprising:
a first heat exchanging plate, comprising a first fin structure disposed protrusively on a side thereof;
a second heat exchanging plate, comprising a second fin structure disposed protrusively on a side thereof; and
a main body, comprising a partition plate, a first communication port, a second communication port, a first recess and a second recess defined therein, the first recess and the second recess located opposite to each other at two sides of the partition plate,
wherein a communication opening is defined on the partition plate, the communication opening communicates with the first recess and the second recess;
wherein the first communication port communicates with the first recess, and the second communication port communicates with the second recess;
wherein a first channel is defined by the first fin structure being accommodated in the first recess, and a second channel is defined by the second fin structure being accommodated in the second recess; and
wherein the first communication port, the first channel, the communication opening, the second channel and the second communication port are connected sequentially in a series.

2. The water-cooling plate according to claim 1, wherein the first heat exchanging plate comprises a first heat exchanging surface, the second heat exchanging plate comprises a second heat exchanging surface, and an area of the first heat exchanging surface is smaller than an area of the second heat exchanging surface.

3. The water-cooling plate according to claim 1, wherein the main body comprises a third communication port and a fourth communication port, the third communication port communicates with the first recess, and the fourth communication port communicates with the second recess.

4. The water-cooling plate according to claim 3, wherein the first heat exchanging plate comprises a third fin structure disposed protrusively thereon, the second heat exchanging plate comprises a fourth fin structure disposed protrusively thereon, a third channel is defined by the third fin structure being accommodated in the first recess, and a fourth channel is defined by the fourth fin structure being accommodated in the second recess.

5. The water-cooling plate according to claim 4, wherein the first channel is non-communicating with the third channel, and the second channel is non-communicating with the fourth channel.

6. The water-cooling plate according to claim 5, wherein a second communication opening communicating with the third channel and the fourth channel is defined on the partition plate.

7. The water-cooling plate according to claim 6, wherein the third channel communicates with the third communication port, and the fourth channel communicates with the fourth communication port.

8. The water-cooling plate according to claim 7, wherein the third communication port, the third channel, the second communication opening, the fourth channel and the fourth communication port are connected sequentially in a series.

9. The water-cooling plate according to claim 1, wherein the main body comprises a pair of slopes, the pair of slopes are disposed outside of the main body, the pair of slopes are disposed opposite to each other at two sides of the partition plate, the pair of slopes are respectively tilted relative to the partition plate, an internal angle is defined between each of the slopes and the partition plate, a plurality of internal angles are a same to each other, and the pair of slops are non-parallel to each other.

10. A water-cooling plate, comprising:
a main body, comprising a partition plate, a first communication port and a second communication port, a first recess and a second recess defined therein, the first recess and the second recess located opposite to each other at two sides of the partition plate;
a first heat exchanging plate, combined with the first recess to define a first chamber, a first channel defined in the first chamber, and the first channel extending on at least a portion of a surface of the first heat exchanging plate in a non-straight path manner; and
a second heat exchanging plate, combined with the second recess to define a second chamber, a second channel defined in the second chamber, and the second channel extending on at least a portion of a surface of the second heat exchanging plate in the non-straight path manner,
wherein a communication opening is defined on the partition plate, the communication opening communicates with the first recess and the second recess;
wherein the first communication port communicates with the first recess, and the second communication port communicates with the second recess; and
wherein the first communication port, the first channel, the communication opening, the second channel and the second communication port are connected sequentially in a series.

11. The water-cooling plate according to claim 10, wherein the first heat exchanging plate comprises a first heat exchanging surface, the second heat exchanging plate comprises a second heat exchanging surface, and an area of the first heat exchanging surface is smaller than an area of the second heat exchanging surface.

12. The water-cooling plate according to claim 10, wherein the first heat exchanging plate is combined with the first recess to define a third chamber, a third channel is defined in the third chamber, and the third channel extending on at least a portion of a surface of the first heat exchanging plate in the non-straight path manner; and
the second heat exchanging plate is combined with the second recess to define a fourth chamber, a fourth channel is defined in the fourth chamber, and the fourth channel extending on at least a portion of a surface of the second heat exchanging plate in the non-straight path manner.

13. The water-cooling plate according to claim 12, wherein the first channel is non-communicating with the third channel, and the second channel is non-communicating with the fourth channel.

14. The water-cooling plate according to claim 13, wherein a second communication opening communicating with the third channel and the fourth channel is defined on the partition plate.

15. The water-cooling plate according to claim 14, wherein the main body comprises a third communication port and a fourth communication port, the third communication port communicates with the first recess, the fourth communication port communicates with the second recess, the third channel communicates with the third communication port, and the fourth channel communicates with the fourth communication port.

16. The water-cooling plate according to claim 15, wherein the third communication port, the third channel, the second communication opening, the fourth channel and the fourth communication port are connected sequentially in a series.

17. The water-cooling plate according to claim 10, wherein the main body comprises a pair of slopes, the pair of slopes are disposed outside of the main body, the pair of slopes are disposed opposite to each other at two sides of the partition plate, the pair of slopes are respectively tilted relative to the partition plate, an internal angle is defined between each of the slopes and the partition plate, a plurality of internal angles are a same to each other, and the pair of slops are non-parallel to each other.
